(19) United States
(12) Patent Application Publication
(10) Pub. No.: US 2014/0109390 A1
(43) Pub. Date: Apr. 24, 2014

(54) Oximeter integrated with wireless devices, that can be worn comfortably on the ear and can be connected to computing devices to provide the wearer information on their heart rate, oxygen saturation, breathing and calories expended whilst the device is worn. Data captured whilst wearing the device can be use at a future time to show, on a computing device, historic readings of the users heart rate, oxygen saturation levels, breathing rate, breathing volume and calories burned.

(71) Applicant: Robert Leslie Manning, London (GB)

(72) Inventor: Robert Leslie Manning, London (GB)

(21) Appl. No.: 13/659,482

(22) Filed: Oct. 24, 2012

(51) Int. Cl. G01R 3/00

(52) U.S. Cl. CPC G01R 3/00
USPC 29/595

(57) ABSTRACT

Wearable Oximeters integrated with wireless devices and computing devices that provide the wearers of the device information on their heart rate, oxygen saturation, breathing and calories expended whilst the device is worn. Using these biometric readings, software on the computing device will enable users to compare the readings from previous sessions when the device was worn. It is envisaged that amateur and professional athletes will use the devices and software to monitor their performance during physical activities.

An Oximeter integrated with wireless devices, that can be worn comfortably on the ear and can be connected to computing devices to provide the wearer information on their heart rate, oxygen saturation, breathing and calories expended whilst the device is worn. Data captured whilst wearing the device can be used at a future time to show, on a computing device, historic readings of the users heart rate, oxygen saturation levels, breathing rate, breathing volume and calories burned. A computing device can also use the historic information to better estimate the users' VO2 max, which in turn is used for calculating number of calories the user expends whilst wearing the device.

### BACKGROUND OF THE INVENTION

Currently there are a number of products on the market that enable cyclists, runners, etc to collect information on their heart rate using a heart rate monitor and typically a sensor belt to send heart rate information of the wearer to a suitable receiver in close proximity.

This invention provides the user with a more convenient and comfortable mechanism of measuring heart rate, particularly for female users, than the strap device. Unlike a wireless strap-on heart rate monitor, this invention can be easily put on and taken off. In addition the invention provides other biometric readings that both amateur and professional athletes will use to understand how they are performing during an exercise session and over time.

### BRIEF SUMMARY OF THE INVENTION

A biometric measuring system that can be conveniently worn by the user and calculates and displays the heart rate, breathing rate, breathing volume, oxygen saturation and calories expended whilst the device is worn.

The system comprises:
Pulse Oximeter with either wired or integrated sensor, wireless transmitter and power source worn on the users earlobe—Ear Unit. This is used to acquire the PhotoPlethysmograph (PPG) signals.
A wireless receiver
Software that interprets the signals from the receiver and converts the signals into heart rate and oxygen saturation levels
Software that derives from the PPG signals the breathing rate and volume
Software that enables the user to store information that the user has input—age, sex, VO2 max.
Software that calculates the calories expended from the heart rate, breathing rate, breathing volume and oxygen saturation levels sampled over a short time period.
Software that enables the user to select which user is wearing the Ear Unit thereby enabling the device to be shared.
Software which from the historic data derived and stored enables a VO2 max rate to be calculated and/or updated.
Software which calculates the calories expended at the time the Ear Unit is worn
Software which displays calories expended

### BRIEF DESCRIPTION OF THE SEVERAL VIEWS OF THE DRAWING

FIG. 1 shows an integrated power source, Oximeter and Transmitter designed to be worn on the ear (Ear Unit). A built-in lanyard prevents accidental loss of the device during use.

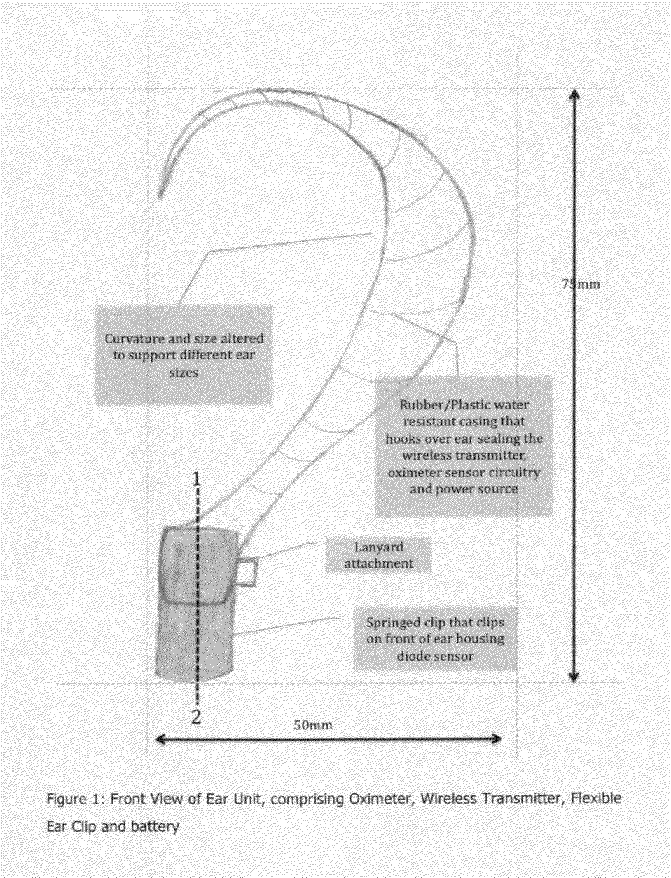

FIG. 2 shows a cross section 1-2 of the Ear Unit, showing the clip, the sensor on the clip and LEDs housing and integrated switch used to turn the Oximeter and Transmitter on/off when worn.

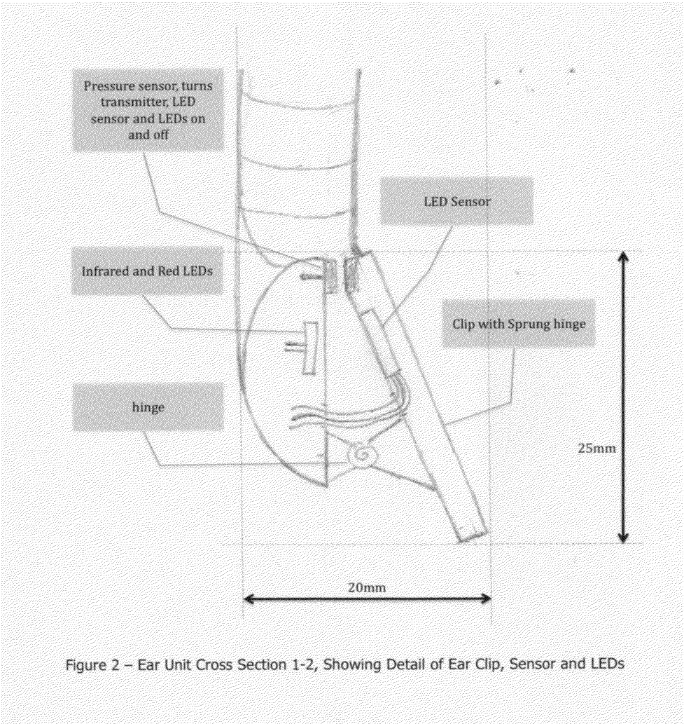

FIG. 3 shows a rear view of the Ear Unit, showing the casing for the battery which can be removed to replace battery.

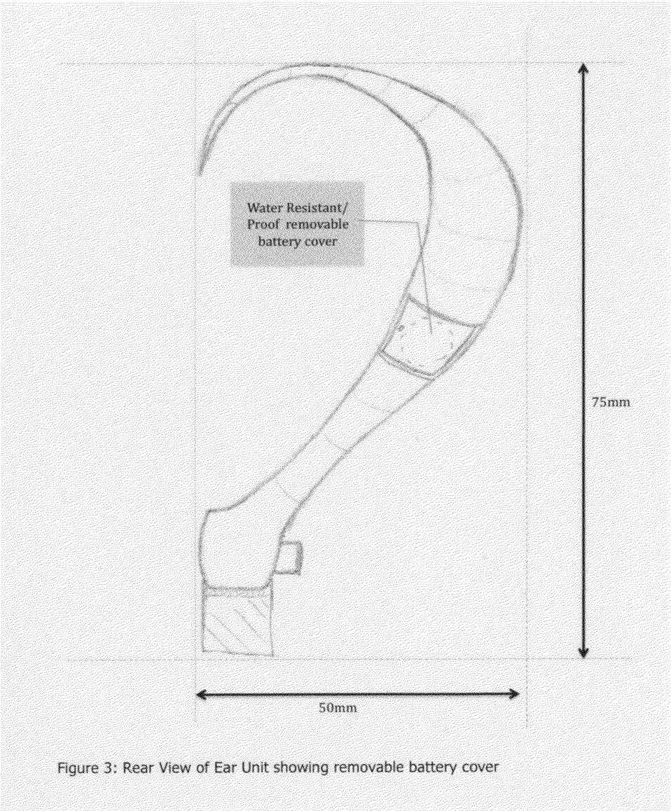

FIG. 4 shows a Receiver connected directly to a cellular phone. The cellular phone provides the power for the Receiver.

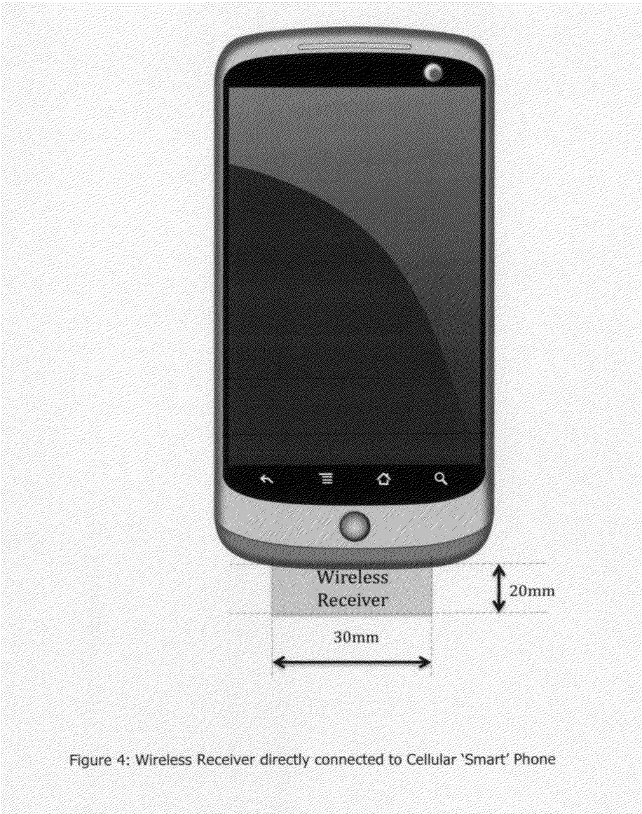

FIG. 5 shows a Receiver connected to a micro controller and power source. The connector converts the signals from the Receiver into data that is stored. The controller includes a USB port enabling it to be connected to computing device that has software associated with this invention installed on it. The controller provides power to the wireless Receiver and has an on/off switch.

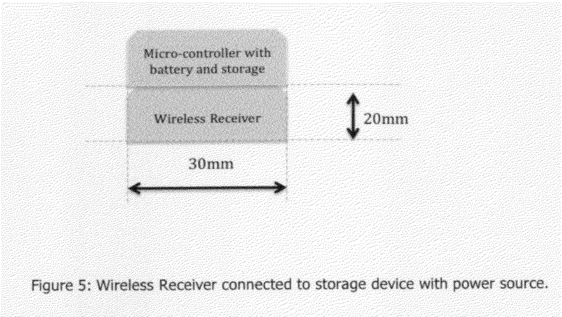

FIG. 6 shows the flow chart describing how the signals detected by the sensor processed by the transmitter and receiver connected to a computing device.

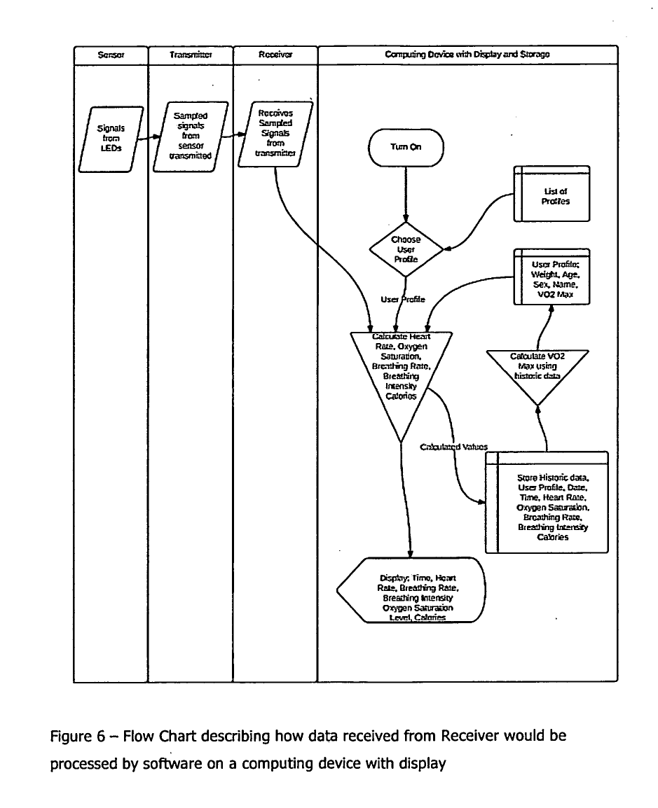

FIG. 7 shows the flow chart describing how data would be read from a file (e.g. USB device as described in FIG. 5) and processed.

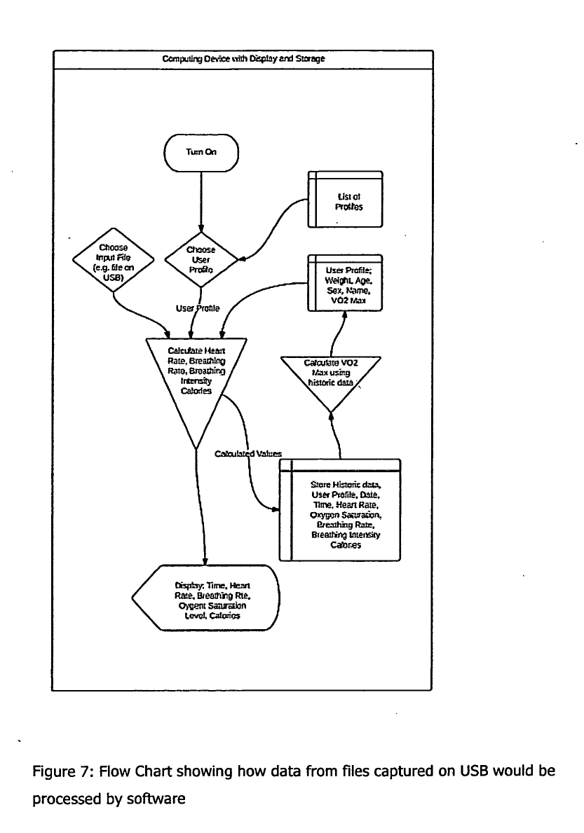

### DETAILED DESCRIPTION OF THE INVENTION

A measuring device (Oximeter) consisting of 2 LEDs, and a photo-detector is used to acquire the PPG signals, using either transmissive, or reflectance measurement. The PPG signals are used to derive the amount of oxygen in the blood, breathing rate and volume, calories, and heart rate of the user. The oximeter is connected to a wireless transmitter and power source.

The wireless transmitter (Transmitter) collects the measurements and/or the sampled PPG waveforms from the Oximeter and transmits them to a wireless receiver (Receiver), sampling the signals from the sensors at approximately 40 Hz (10 times the assumed maximum heart rate).

The Oximeter, Transmitter and power source (small battery) are housed in a unit that fits comfortably over the human ear—Ear Unit. The unit is made of water resistant material and has a texture that means it will not slip easily once it is put on the ear. The material is also flexible allowing the user to shape it to be a more comfortable fit to their ear, retaining the formed shape until readjusted.

The Transmitter and Oximeter are turned on when circuitry in the Ear Unit detects a break in the contacts on the device, when the ear clip, integrated with the Ear Unit, is opened and clipped on to the ear.

A receiver (Receiver), in close proximity to the Ear Unit, automatically detects the unit's presence and starts to process the signals being transmitted. The Receiver is connected to a computing device, e.g. computer, mobile phone, that has software that collects the PPG signals, and/or readings and may processes them to further calculate heart rate, breathing rate, breathing volume, oxygen levels in the blood and calories being expended. This information is displayed on the computing device.

The Ear Unit and Wireless Receiver are referred to in this document as The Hardware.

Software on a computing device connected to The Hardware, calculates and displays the heart rate, breathing rate, breathing volume, oxygen levels in the blood and calories (Readings) whilst the user is wearing the Ear Unit and the Receiver and computing device are in close proximity (3-4 meters) of the Ear Unit.

Software on a computing device, not necessarily connected to The Hardware, stores the data collected and allows the user to view the data gathered by the Hardware at a previous collection time.

Software on a computing device, not necessarily connected to the Hardware allows the user to compare (numerically and graphically) Readings from recent and previous historical sessions.

Software on a computing device enables the user to export the data to be combined with other computing software, e.g. GPS software that shows the user where they were (latitude,longitude,elevation,date,time) when they were wearing the Hardware.

Software on a computing device enables the user to optionally input other biometric data such as their age, sex, weight, height, BMI and VO2 max, if known—a user's Profile. If this information is entered software on the computing device will calculate the calories being expended whilst the user is wearing the Ear Unit using the Readings. If this information is not entered an approximation for calories expended will be calculated based on default values.

Software on the computing device will use historic data to calculate and/or update the VO2 max variable for the user and use this value, when connected to the Hardware, to calculate the calories expended by the wearer.

Software on the computing device will also allow the user to share the Hardware by allowing the user to store multiple Profiles.

The Ear Unit and Receiver, can be worn in all sorts of scenarios: cycling, running, walking, ski-ing, climbing, fitness training etc.

A water proof Ear Unit, Receiver and computing device can be created using water proof casings to contain each piece.

What is claimed is:

1. The method for creating convenient, comfortable wearable devices (Ear Unit) that can be worn on the ear and used by anyone to measure and wirelessly transmit the PPG signals, and/or derived parameters: heart rate, breathing rate, breathing volume, calories, and blood oxygen levels to a nearby wireless receiver.

2. The method of claim 1, further comprising a wireless receiver that can be physically connected to computing devices such as a cellular phone, personal computer, tablet computer or purpose built device. The power for the wireless receiver is provided by the computing device.

3. The method of claim 2, further comprising software that can calculate the heart rate, oxygen level, breathing rate, breathing volume and calories used by the user of the Ear Unit from the PPG signals.

4. The method of claim 3, further comprising software that displays to the wearer of the Ear Unit their current heart rate, oxygen level, calories, breathing volume and breathing rate of the user at the time the Ear Unit is being worn.

5. The method of claim 4, further comprising software that stores the heart rate, oxygen level, breathing rate, breathing volume and calories used with the time the data was collected.

6. The method of claim 5, further comprising software that displays the heart rate, oxygen level, breathing rate, breathing volume and calories used against time, in graphical format.

7. The method of claim 6, further comprising software that enables the user to export the data collected and import to other software programs, such as those that show the user their location (latitude,longitude,elevation) at a point in time.

8. The method of claim 6, further comprising a method that enables the user to enter and store biometric data on the device such as weight, age, height, VO2 max

9. The method of claim 2, further comprising a wireless receiver that can be connected wirelessly (e.g. using Bluetooth) to a computing device.

10. The method of claim 6, further comprising a method that enables the user to enter upper and lower limits for heart rate, breathing rate, breathing volume, oxygen levels and calories.

11. The method of claim 10, further comprising a method for indicating by sound and/or on a display if these limits are being approached or exceeded.

12. The method of claim 8, further comprising a method that enables the user to have multiple combinations of weight, age, height, VO2 max called a profile—thereby enabling the user to share the Ear Unit.

13. The method of claim 5 and claim 8 further comprising software that approximates the calculation of VO2 max derived from the historic information collected and weight and age input by the user

14. The method of claim 1 further comprising a mechanism for automatically turning off the power source to the Ear Unit.

15. The method of claim 1, further comprising a wireless receiver with a microcontroller, storage device and power source and usb interface. The power source powers both the controller and the wireless receiver.

16. The method of claim 15, further comprising software that can be installed on computing devices that will read the data stored on storage device and allow it to be downloaded for processing as if the Receiver had been connected to the computing device.
